(19) United States
(12) Patent Application Publication
(10) Pub. No.: US 2024/0275185 A1
(43) Pub. Date: Aug. 15, 2024

(54) Battery Pack Voltage Measurement Circuit And Operation Method Thereof

(71) Applicant: LG Energy Solution, Ltd., Seoul (KR)

(72) Inventor: Kang San Kim, Daejeon (KR)

(73) Assignee: LG Energy Solution, Ltd., Seoul (KR)

(21) Appl. No.: 18/561,447

(22) PCT Filed: Oct. 28, 2022
(86) PCT No.: PCT/KR2022/016677

§ 371 Date: Nov. 16, 2023

(30) Foreign Application Priority Data
Nov. 2, 2021 (KR) 10-2021-0148907

(51) Int. Cl. H02J 7/00

(52) U.S. Cl. CPC H02J 7/0031; H02J 7/0013; H02J 7/0047

(57) ABSTRACT

Provided is a fire prevention apparatus including a switch connected to a battery through a first line, a variable resistor connected to the switch, a fuse connected to the variable resistor and a second line connecting the battery with a device powered from the battery, a sensor configured to sense information about battery fire, and a controller configured to control the switch and the variable resistor based on the information about the battery fire.

### CROSS-REFERENCE TO RELATED APPLICATIONS

The present application is a national phase entry under 35 U.S.C. § 371 of International Application No. PCT/KR2022/016607 filed Oct. 28, 2022, which claims priority from Korean Patent Application No. 10-2021-0148907 filed Nov. 2, 2021, all of which are incorporated herein by reference.

### TECHNICAL FIELD

The present invention relates to a battery pack voltage measurement circuit and a method for operating the same, and more particularly, to a battery pack voltage measurement circuit for measuring a voltage of a battery pack and outputting a result value thereof, and a method for operating the same.

### BACKGROUND ART

Recently, as the demand for electric and electronic devices is rapidly increasing, interest in battery packs is also increasing. Since the battery pack used as a storage battery or a secondary battery is an essential component for driving the electric and electronic devices, the battery pack is continuously developing along with the electric and electronic devices.

Meanwhile, as the issue of eco-friendly technology is amplified around the world, products related to electric vehicles and solar module are being mass-produced explosively. Since electric vehicles and solar modules are also basically configured with the battery pack, the demand for the battery pack is increasing. The battery pack is being developed to be used longer and driven more powerfully according to consumer demand. That is, the battery pack is developing into a battery pack with a high-capacity and high-voltage specifications.

The high-voltage specifications for the battery pack provides more powerful driving power to a peripheral circuitry that uses the battery pack in an ideal situation, but causes serious damage to the peripheral circuitry in a situation where unwanted problems arise. Therefore, measuring and managing a voltage of the battery pack in order to prevent an abnormal current from occurring in the battery pack can be regarded as an essential item in the battery pack. Therefore, the battery pack is configured together with the battery pack voltage measurement circuit for this purpose.

The battery pack voltage measurement circuit includes a relay switch and an analog to digital converting (ADC) output circuit. The relay switch of the battery pack voltage measurement circuit can perform an on or off operation based on an overcurrent, and the ADC output circuit can measure a voltage of the battery pack according to a current flowing through the relay switch.

Meanwhile, the voltage of battery pack used in the electric vehicles is increasing from 400 V to 800 V. Accordingly, the battery pack voltage measurement circuit should also be designed to match an increased voltage of the battery pack. To this end, the relay switch configured in the battery pack voltage measurement circuit should satisfy an allowable voltage value of 800 V. However, in the case of a relay switch that operates stably at the allowable voltage value of 800 V, a switch having very high price, i.e., a relay switch with high specifications is required because advanced process technology is required and high-quality materials should be used. If a relay switch with low specifications having an allowable voltage value of 400 V is used to measure a voltage of the battery pack of 800 V, the OFF time of the relay switch may be delayed, and thus various problems due to this delay may be caused.

In this regard, Japanese patent registration No. 4385640 (registration date: 2009.10.09.) and Korean patent registration No. 1211055 (registration date: 2012.12.05.) disclose a configuration for detecting the voltage of the battery pack. The two patent documents disclose a relay switch that is directly connected to the voltage of the battery pack. In this case, as described above, if a relay switch with high specifications is not used, a smooth measurement operation for the high voltage battery pack is impossible.

Related art includes the following prior art.
Patent literature 1: JP 4385640 B2 (2009.10.09.)
Patent literature 2: KR 1211055 B1 (2012.12.05.)

### SUMMARY

### Technical Problem

Therefore, the present invention is intended to provide a battery pack voltage measurement circuit capable of stably operating a relay element of low specifications even when a voltage of a battery pack is high, and a method for operating the same.

### Technical Solution

In order to achieve the object described above, according to an aspect of the present invention, there is provided a battery pack voltage measurement circuit including a first resistor, the relay circuit, a second resistor, and an ADC output circuit, wherein the first resistor, a relay circuit, the second resistor, and the ADC output circuit are sequentially connected in series between a power supply voltage terminal to which a voltage of a battery pack is applied and a ground voltage terminal, in which the relay circuit comprises a relay element and a relay resistor in parallel.

Further, when the relay element is turned off, a first voltage applied to both ends of the relay element may be the same as a second voltage applied to both ends of the relay resistor.

Further, a resistance value Rᵣ of the relay resistor may satisfy the following

### [Equation 1].

$$\frac{{R}_{r}}{( {R}_{1} + {R}_{2} + {R}_{3} )} \times {V}_{o} < {V}_{lim} \qquad [ Equatio$$

wherein, R₁ and R₂ are resistance values of the first and second resistors, respectively, Vₗᵢₘ is an allowable voltage value of the relay element, and Vₒ is a voltage value of the battery pack.

In addition, a resistance value Rᵣ of the relay resistor may satisfy the following [Equation 2].

$$\frac{{R}_{r}}{( {R}_{1} + {R}_{2} + {R}_{c} + {R}_{r} )} \times {V}_{o} < {V}_{lim} \qquad [ Equatio$$

wherein R₁ and R₂, and Re are first and second resistors and a resistance value of the ADC output circuit, respectively, Vₗᵢₘ is an allowable voltage value of the relay element, and Vₒ is a voltage value of the battery pack.

In order to achieve the object described above, according to another aspect of the present invention, there is provided a method for operating a battery pack voltage measurement circuit, the method including dropping a voltage applied to measure a battery pack voltage, determining an “on” state of a relay element according to the battery pack voltage, setting a first voltage across the relay element to be the same as a second voltage across the relay resistor based on the result of determining the “on” state of the relay element, and detecting the battery pack voltage.

In order to achieve the object described above, according to still another aspect of the present invention, there is provided a battery pack voltage measurement circuit including a voltage drop circuit, a relay circuit, and an ADC output circuit, wherein the voltage drop circuit, the relay circuit, and the ADC output circuit are connected in series between a power supply voltage terminal to which a voltage of a battery pack is applied and a ground voltage terminal, in which the relay circuit comprises a relay element and a relay resistor in parallel.

Further, the voltage drop circuit may include a resistor connected between the power supply voltage terminal and the relay circuit wherein the voltage drop circuit is configured to drop a voltage applied to the power supply voltage terminal.

Further, battery pack voltage measurement circuit may include a resistor connected between the relay circuit and the ADC output circuit, wherein the resistor is configured to drop and divide a voltage applied to the relay circuit.

### Advantageous Effects

As described above, according to the present invention, it is possible to use a relay element of low specifications having a low allowable voltage value by dropping the voltage of the battery pack applied to the relay circuit.

That is, the present invention includes the first resistor, the relay circuit, the second resistor, and the ADC output circuit that are sequentially connected in series between the power supply voltage terminal to which the voltage of the battery pack is applied and the ground voltage terminal, and the relay circuit detects the voltage of the battery pack by connecting the relay element and the relay resistor in parallel.

In this case, the relay element configured in the relay circuit can be used as a relay element of low specifications through the series connection structure of the first and second resistors and the parallel connection structure of the relay resistors. Therefore, even if the voltage of the battery pack to be detected increases, the manufacturing cost of the battery pack voltage measurement circuit can be reduced by using a relay element of low specifications having a low price instead of a relay element of high specifications having an expensive price.

### BRIEF DESCRIPTION OF THE DRAWINGS

FIG. 1 is a diagram illustrating a battery pack voltage measurement circuit according to an embodiment of the present invention.

FIG. 2 is a flowchart illustrating a method for operating the battery pack voltage measurement circuit of FIG. 1.

FIG. 3 is a diagram illustrating a battery pack voltage measurement circuit according to another embodiment of the present invention.

FIG. 4 is a diagram illustrating a battery pack voltage measurement circuit according to the related art.

### DETAILED DESCRIPTION

Hereinafter, embodiments of the present invention will be described in detail with reference to the accompanying drawings. However, the present invention is not limited to the embodiments disclosed below, but will be implemented in various different forms. The embodiments of the present invention are provided only to complete the disclosure of the present invention, and to fully inform those of ordinary skill in the scope of the present invention. In the drawings, the same reference numerals refer to the same elements.

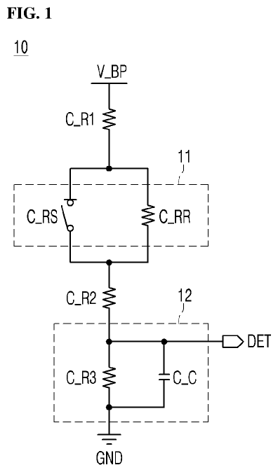

FIG. 1 is a diagram illustrating a battery pack voltage measurement circuit 10 according to an embodiment of the present invention.

Referring to FIG. 1, the battery pack voltage measurement circuit 10 according to an embodiment of the present invention includes a first resistor C_R1, a relay circuit 11, a second resistor C_R2, and an ADC output circuit 12. Here, the first resistor C_R1, the relay circuit 11, the second resistor C_R2, and the ADC output circuit 12 are sequentially connected in series between a power supply voltage terminal V_BP to which a voltage of a battery pack (not illustrated) is applied and a ground voltage terminal GND.

The first resistor C_R1 is connected between the power supply voltage terminal V_BP and the relay circuit 11. The first resistor C_R1 drops the voltage of the battery pack applied from the power voltage terminal V_BP to provide the voltage to the relay circuit 11. Accordingly, even when the voltage of the battery pack of, for example, 800 V is applied to the power supply voltage terminal V_BP, the voltage dropped by the first resistor C_R1 is applied to the relay circuit 11.

The relay circuit 11 includes a relay element C_RS and a relay resistor C_RR. Here, the relay element C_RS and the relay resistor C_RR are configured to be connected in parallel between the first resistor C_R1 and the second resistor C_R2 in series.

The relay element (C_RS) is not illustrated in detail in the drawing, but may be configured with a solenoid and a switch. In the relay element C_RS, an on or off operation of a switch may be controlled based on magnetic force generated in the solenoid. The relay resistor C_RR is connected in parallel with the relay. Accordingly, when the relay element C_RS is turned OFF, the voltage applied to both ends of the relay element C_RS is the same as the voltage applied to both ends of the relay resistor C_RR.

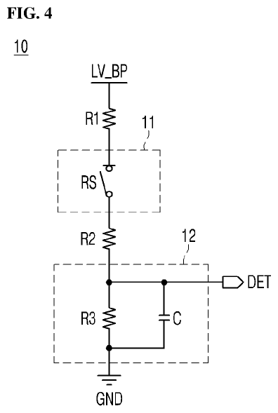

The circuit configuration of the present invention as described above solves the problem that a high-rated relay is required for the case of a system with a high pack voltage, e.g., 800 V because most of LV_BP is applied to both ends of the relay element RS when the relay element RS is turned OFF in the related art as illustrated in FIG. 4. In the present invention, due to the relay resistance C_RR, only a low level pack voltage, which is a part of the pack voltage, is applied even when the relay is turned OFF, and thus, an effect of capable of applying, e.g., a relay rated for a 400 V system to an 800 V system is achieved.

That is, since the voltage dropped by the first resistor C_R1 is applied to one side of the relay element C_RS, the relay element C_RS may be designed as a relay element of low specifications. Also, since the voltage dropped by the first resistor C_R1 and the relay resistor C_RR is applied to the other side of the relay element C_RS, a stable on or off operation can be guaranteed even when the relay element C_RS is used as the relay element of low specifications.

The second resistor C_R2 is connected between the relay circuit 11 and the ADC output circuit 12. The second resistor C_R2 is a configuration for dropping and distributing the voltage applied to the relay circuit 11, and as will be described later by equations, a more stable voltage may be applied to both ends of the relay element C_RS through the second resistor C_R2.

The ADC output circuit 12 includes a third resistor R3 and a capacitor C. Here, the third resistor R3 and the capacitor C are configured to be connected in parallel between the second resistor C_R2 and the ground voltage terminal GND. The ADC output circuit 12 converts an analog voltage transferred through the second resistor C_R2 into a digital voltage to generate a detection signal DET corresponding to the voltage of the battery pack. Since a circuit operation of the ADC output circuit 12 is already known, a detailed description thereof will be omitted.

Meanwhile, a resistance value Rᵣ of the relay resistor C_RR is determined to satisfy [Equation 1] below.

$$\frac{{R}_{r}}{( {R}_{1} + {R}_{2} + {R}_{3} )} \times {V}_{o} < {V}_{lim} \qquad [ Equation 1 ]$$

[Equation 1] is an expression excluding the ADC output circuit 12 for convenience of explanation. Here, R₁ and R₂ are resistance values of the first and second resistors C_R1 and C_R2, respectively, Vₗᵢₘ is an allowable voltage value of the relay element C_RS, and Vₒ is a voltage value of the battery pack.

As can be seen from [Equation 1], the allowable voltage value Vₗᵢₘ of the relay element C_RS should be smaller than the voltage value Vₒ of the battery pack. In this case, a voltage drop of the voltage value Vₒ of the battery pack is made by the resistance values R₁, R₂, and Rᵣ of the first and second resistors C_R1 and C_R2 and the relay resistor C_RR, respectively. Therefore, even if the voltage value Vₒ of the battery pack increases, for example, from 400 V to 800 V, if the resistance values R₁, R₂, and Rᵣ of the first and second resistors C_R1 and C_R2 and the relay resistor C_RR are appropriately designed, the allowable voltage value Vₗᵢₘ of the relay element C_RS may be satisfied. Here, the fact that the allowable voltage value Vₗᵢₘ of the relay element C_RS is satisfied even when the voltage value Vₒ becomes 800 V means that the voltage Vₒ of the battery pack having a high voltage can be measured stably even if a relay element of low specifications is used.

Further, when the relay element (C_RS) is turned OFF, the voltage dropped by the first resistor R₁ is applied to one end of the relay element C_RS, and a voltage equal to the voltage applied to both ends of the relay resistor C_RR is applied to both ends of the relay element C_RS. Therefore, even when a relay element of low specifications is used for the relay element C_RS, the off operation of the relay element C_RS can be stably performed.

As described above, through this configuration and operation, the battery pack voltage measurement circuit 10 according to the embodiment of the present invention provides an environment in which a relay element of low specifications can be used for the relay element C_RS.

On the other hand, the resistance value Rᵣ of the relay resistor C_RR is determined to satisfy [Equation 2] below.

$$\frac{{R}_{r}}{( {R}_{1} + {R}_{2} + {R}_{c} + {R}_{r} )} \times {V}_{o} < {V}_{lim} \qquad [ Equation 2 ]$$

[Equation 2] is an expression including the ADC output circuit 12. Here, R₁ and R₂, and R_{c} are the resistance values of the first and second resistors C_R1 and C_R2, and the resistance values of the ADC output circuit 12, respectively, and Vₗᵢₘ is the allowable voltage value of the relay element C_RS, and Vₒ is the voltage value of the battery pack.

[Equation 2] also like [Equation 1], the allowable voltage value Vₗᵢₘ of the relay element C_RS may be smaller than the voltage value Vₒ of the battery pack, and a voltage drop of the voltage value Vₒ of the battery pack is made by R₁ and R₂, R_{c}, and Rᵣ, which are the resistance values of the first and second resistors C_R1 and C_R2, the ADC output circuit 12, and the relay resistor C_RR, respectively. In particular, [Equation 2] means that the voltage value Vₒ of the battery pack can be controlled lower by the resistance value R_{c} of the ADC output circuit 12. This means that even if the voltage value Vₒ of the battery pack becomes higher, it can be included in the allowable voltage value Vₗᵢₘ of the relay element C_RS.

As described above, since the battery pack voltage measurement circuit 10 according to the embodiment of the present invention can use the relay element C_RS of low specifications, the battery pack voltage measurement circuit 10 can be mass-produced at a lower manufacturing cost.

The embodiment of the present invention will be described with specific values of resistance values and pack voltage applied to the circuit of the present invention of FIG. 1 and the circuit of the related art of FIG. 4.

In the related art of FIG. 4, when a pack voltage LV_BP is 400 V and the relay is turned ON, the pack voltage should be detected by being subjected to ADC at a ratio of 100:1 in order to match an ADC input limit of 5 V, and thus each of R₁ and R₂ may be set to 1 MΩ and R₃ may be set to 20 kΩ. In this case, when the relay is turned OFF, an applied resistance value RS of a predetermined relay corresponds to about 10\hat{ }14Ω, so that most of the pack voltage is applied to the relay. That is, in order to apply the circuit of the related art of FIG. 4 to a high voltage system in which the pack voltage is 800 V, an expensive relay corresponding to the 800 V system should be used.

On the other hand, in the detection circuit of the present invention in FIG. 1, a pack voltage V_BP is 800 V, and when the relay is turned ON, the pack voltage should be detected by being subjected to ADC at a ratio of 200:1 to match the ADC input limit value of 5 V. Therefore, C_R1 and C_R2 may be set to 6 MΩ, 3 MΩ, and R3 to 45 kΩ, respectively. In this case, unlike the prior art, if the relay resistance C_RR is added in parallel and set to 10 MΩ, when the relay is turned OFF, a pack voltage of 10 M/19.45 M is applied to both ends of the relay, and only about half of the pack voltage is applied. Therefore, it becomes possible to apply a relay having the same level of rating as in a system having a pack voltage of 400 V.

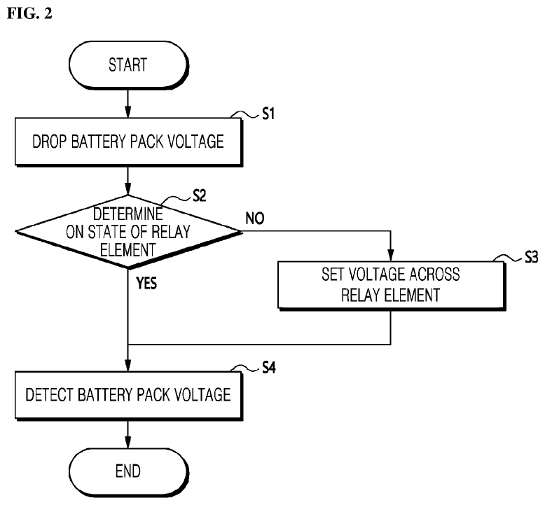

FIG. 2 is a flowchart illustrating a method for operating the battery pack voltage measurement circuit 10 of FIG. 1.

Referring to FIGS. 1 and 2, the method for operating the battery pack voltage measurement circuit 10 includes a process S1 of dropping the battery pack voltage, a process S2 of determining the ON state of the relay element, a process S3 of setting the voltage across the relay element, and a process S4 of detecting the battery pack voltage.

The process of dropping the battery pack voltage S1 is a process of dropping the battery pack voltage applied from the power supply voltage terminal V_BP to measure the voltage of the battery pack. The process S1 of dropping the battery pack voltage may be performed by the first to third resistors C_R1, C_R2, and C_R3 of FIG. 1.

The process S2 of determining the ON state of the relay element is a process of determining the ON state of the relay element C_RS (see FIG. 1) according to the battery pack voltage. If the relay element C_RS is in an OFF state (No), the process S3 to be described later is performed. If the relay element C_RS is in an ON state (Yes), the process S4 to be described later is performed.

The process S3 of setting the voltage across the relay element is a process of setting the voltage across the relay element C_RS to be the same as the voltage across the relay resistor C_RR when the relay element C_RS is in the OFF state (No), based on the result of the determining process S2. The process S3 of setting the voltage across the relay element may be performed by the relay resistor C_RR of FIG. 1.

The process S4 of detecting the battery pack voltage is a process of detecting an analog type battery pack voltage applied from the power supply voltage terminal V_BP and outputting it as a digital type detection signal DET. The process S4 of detecting the battery pack voltage may be performed in the ADC output circuit 12 of FIG. 1.

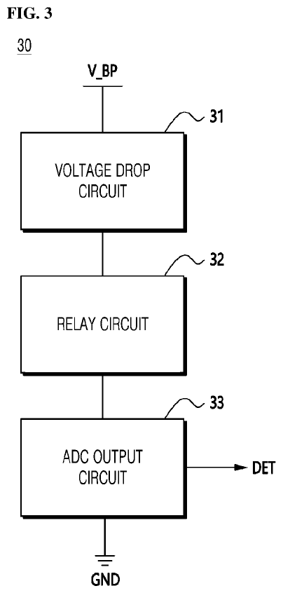

FIG. 3 is a diagram illustrating a battery pack voltage measurement circuit 30 according to another embodiment of the present invention.

Referring to FIG. 3, the battery pack voltage measurement circuit 30 according to another embodiment of the present invention includes a voltage drop circuit 31, a relay circuit 32, and an ADC output circuit 33. Here, the voltage drop circuit 31, the relay circuit 32, and the ADC output circuit 33 are sequentially connected in series between the power supply voltage terminal V_BP to which a voltage of a battery pack (not illustrated) is applied and the ground voltage terminal GND.

The voltage drop circuit 31 is a configuration connected between the power supply voltage terminal V_BP and the relay circuit 22 and for dropping the voltage applied to the power supply voltage terminal V_BP. The voltage drop circuit 31 may correspond to the first resistor C_R1 of FIG. 1. As already described in FIG. 1, the voltage drop circuit 31 drops the voltage of the battery pack applied to the power supply voltage terminal V_BP through the first resistor C_R1 to provide it to the relay circuit 32.

The relay circuit 32 is configured with the relay element C_RS and the relay resistor C_RR of FIG. 1. The ADC output circuit 33 is configured with the third resistor C_R3 and the capacitor C_C of FIG. 1. Since the configuration and operation of the relay circuit 32 and the ADC output circuit 33 have been sufficiently described with reference to FIG. 1, a more detailed description thereof will be omitted.

Meanwhile, the battery pack voltage measurement circuit 30 further includes the second resistor C_R2 of FIG. 1 connected between the relay circuit 32 and the ADC output circuit 33. As described in FIG. 1, the second resistor C_R2 is a configuration for dropping and distributing the voltage applied to the relay circuit 32.

As described above, since the battery pack voltage measurement circuit 30 according to the embodiment of the present invention can use the relay element C_RS with low specifications, the battery pack voltage measurement circuit 30 can be mass-produced at a lower manufacturing cost.

In the above, preferred embodiments of the present invention have been described and illustrated using specific terms, but such terms are only for clearly describing the present invention. It is obvious that various alterations and changes can be made to the embodiments and described terms of the present invention without departing from the spirit and scope of the following claims. Such modified embodiments should not be separately understood from the spirit and scope of the present invention, but should be considered to fall within the scope of the claims of the present invention.

Although the battery pack voltage measurement circuit and the method for operating the same have been described with reference to the specific embodiments, they are not limited thereto. Therefore, it will be readily understood by those skilled in the art that various modifications and changes can be made thereto without departing from the spirit and scope of the present invention defined by the appended claims.

1. A battery pack voltage measurement circuit comprising:
a first resistor;
a relay circuit;
a second resistor; and
an ADC output circuit, wherein the first resistor, the relay circuit, the second resistor, and the ADC output circuit are sequentially connected in series between a power supply voltage terminal to which a voltage of a battery pack is applied and a ground voltage terminal, wherein the relay circuit comprises a relay element and a relay resistor in parallel.

2. The circuit of claim 1, wherein
when the relay element is turned off, a first voltage applied to both ends of the relay element is the same as a second voltage applied to both ends of the relay resistor.

3. The circuit of claim 1, wherein
a resistance value Rᵣ of the relay resistor to satisfy the following [Equation 1],
$$\frac{{R}_{r}}{( {R}_{1} + {R}_{2} + {R}_{3} )} \times {V}_{o} < {V}_{lim} \qquad [ Equation 1 ]$$
wherein, R₁ and R₂ are resistance values of the first and second resistors, respectively, Vₗᵢₘ is an allowable voltage value of the relay element, and Vₒ is a voltage value of the battery pack.

4. The circuit of claim 1, wherein
a resistance value Rᵣ of the relay resistor satisfies the following [Equation 2],
$$\frac{{R}_{r}}{( {R}_{1} + {R}_{2} + {R}_{c} + {R}_{r} )} \times {V}_{o} < {V}_{lim} \qquad [ Equation 2 ]$$
wherein R₁ and R₂, and Re are first and second resistors and a resistance value of the ADC output circuit, respectively, Vₗᵢₘ is an allowable voltage value of the relay element, and Vₒ is a voltage value of the battery pack.

5. A method for operating a battery pack voltage measurement circuit, the method comprising:
dropping a voltage applied to measure a battery pack voltage;
determining an “on” state of a relay element according to the battery pack voltage;
setting a first voltage across the relay element to be the same as a second voltage across the relay resistor based on the result of determining the “on” state of the relay element; and
detecting the battery pack voltage.

6. A battery pack voltage measurement circuit comprising:
a voltage drop circuit;
a relay circuit; and
an ADC output circuit, wherein the voltage drop circuit, the relay circuit, and the ADC output circuit are connected in series between a power supply voltage terminal to which a voltage of a battery pack is applied and a ground voltage terminal, wherein
the relay circuit comprises a relay element and a relay resistor in parallel.

7. The circuit of claim 6, wherein
the voltage drop circuit comprises a resistor connected between the power supply voltage terminal and the relay circuit, wherein the voltage drop circuit is configured to drop a voltage applied to the power supply voltage terminal.

8. The circuit of claim 6, further comprising:
a resistor connected between the relay circuit and the ADC output circuit, wherein the resistor is configured to drop and divide a voltage applied to the relay circuit.
